(19) United States
(12) Patent Application Publication
(10) Pub. No.: US 2026/0176755 A1
(43) Pub. Date: Jun. 25, 2026

(54) EXTERNAL PART COMPRISING A COATING OF INTERFERENCE LAYERS DEPOSITED ON A FACE MADE OF A MATERIAL COMPRISING AT LEAST 50% BY MASS OF ALUMINIUM

(71) Applicant: The Swatch Group Research and Development Ltd, Marin (CH)

(72) Inventors: Camille HALLER, Yverdon-Ies-Bains (CH); Loïc CURCHOD, Lausanne (CH); Marie BAUDOZ, Morteau (FR); Giovanni POLY, Maiche (FR)

(73) Assignee: The Swatch Group Research and Development Ltd, Marin (CH)

(21) Appl. No.: 19/374,227

(22) Filed: Oct. 30, 2025

(30) Foreign Application Priority Data
Dec. 20, 2024 (EP) 24222587.8

(51) Int. Cl. C23C 16/455; C23C 16/40; C23C 16/52

(52) U.S. Cl. CPC C23C 16/45525; C23C 16/403; C23C 16/405; C23C 16/52

(57) ABSTRACT

An external part (10) used in horology, jewellery or fine jewellery, characterised in that it includes a substrate (100) having a support face (101) made of a material with at least 50% by mass of aluminium, on which is deposited a semi-transparent thin-film dielectric coating (110) having at least two layers, including a base layer (111) made of Al₂O₃ overlying the support face (101), and a terminal layer (112) made of TiO₂.

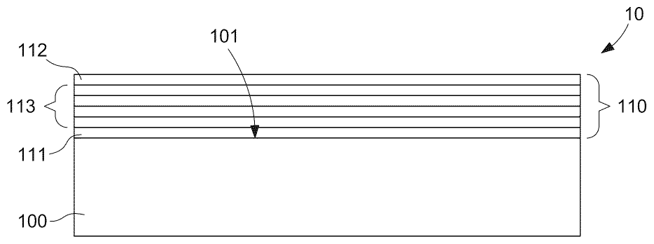

### CROSS-REFERENCE TO RELATED APPLICATIONS

This application claims priority to European Patent Application No. 24222587.8, filed on Dec. 20, 2024, the entire contents of which are incorporated herein by reference.

### TECHNICAL FIELD OF THE INVENTION

The invention relates to the field of horology, jewellery or fine jewellery, and more specifically to an external part for use in horology, jewellery or fine jewellery.

In this specification, the term “external part” refers, as is commonly understood in the aforementioned fields, to a component that is visible to a user and has a decorative function, meaning that it contributes to the visual appearance of an object.

### TECHNOLOGICAL BACKGROUND

In the fields of horology, jewellery and fine jewellery, market players are constantly on the lookout for new decorative solutions to change the appearance of their products in order to enhance product appeal or to stand out from the competition.

For example, and particularly in the field of horology, it is common to colour external parts by depositing thin layers on a substrate using vacuum deposition methods, such as physical vapour phase deposition or chemical vapour phase deposition. However, depending on the nature of the substrate and of the layers deposited, adhesion problems may arise. This drawback requires the deposition of an adhesion layer, which further complicates the component colouring method.

With regard to external parts comprising a substrate made of aluminium, the aforementioned drawback can be remedied by using a method for anodising the substrate in order to colour the external part. However, anodising is a relatively long process insofar as it requires long cycle times to grow an oxide layer on the substrate and involves a multitude of steps. Moreover, between each step, the external parts have to be handled, which increases the risk of damaging them.

### SUMMARY OF THE INVENTION

The invention remedies the aforementioned drawbacks and relates to an external part used in horology, jewellery or fine jewellery, characterised in that it comprises a substrate having a support face made of a material comprising at least 50% by mass of aluminium, on which is deposited a thin-film dielectric coating comprising at least two layers, including a base layer made of Al₂O₃ overlying the support face, and a terminal layer made of TiO₂.

The invention advantageously ensures excellent adhesion between the support face and the thin-film dielectric coating due to the chemical affinity between said face and the base layer. Layering can also be used to impart a bright and precise colour to the external part.

Furthermore, the present invention is an advantageous alternative to colouring an aluminium substrate by anodisation, with none of the drawbacks associated with that process. In fact, the layers in the thin-film dielectric coating are deposited using a method for depositing thin atomic layers known to persons skilled in the art by the acronym “ALD,” which stands for “Atomic Layer Deposition” and which makes it possible to colour an aluminium substrate quickly and easily with no need to handle the external part between the deposition of each layer.

In some particular embodiments, the invention can further comprise one or more of the following features, taken separately or in any technically possible combination.

In some particular embodiments, the external part comprises an even number of intermediate layers, and at least two of said intermediate layers are deposited between the base layer and the terminal layer and are alternately made of TiO₂ and Al₂O₃ such that the intermediate layer overlying the base layer is made of TiO₂ and the layer in contact with the terminal layer is made of Al₂O₃.

In some particular embodiments, the substrate is formed by a body made of pure aluminium or of an aluminium alloy and comprising the support face.

In some particular embodiments, the substrate comprises a body on which is formed a plating made of aluminium nitride, aluminium carbide, aluminium oxide or aluminium carbonitride, the plating comprising the support face.

In some particular embodiments, the thin-film dielectric coating comprises four intermediate layers.

In some particular embodiments, the layers in the thin-film dielectric coating have thicknesses chosen so as to impart an interference colour to the external part characterised, in the CIELAB space in the reflection mode of the standardised illuminant D65, with an observer of 10° and a measurement geometry of di:8°, by the parameters L*=[75; 85], a*=[−45; −35], b*=[5; 15].

In some particular embodiments, the base layer has a thickness comprised between 1 nm and 10 nm, the intermediate layers have a thickness comprised between 20 nm and 90 nm, and the terminal layer has a thickness comprised between 55 nm and 65 nm.

In some particular embodiments, the intermediate layers taken successively from the intermediate layer closest to the base layer to the intermediate layer closest to the terminal layer have a thickness comprised between 25 nm and 30 nm, between 75 nm and 85 nm, between 15 nm and 25 nm and between 15 nm and 25 nm, respectively.

### BRIEF DESCRIPTION OF THE FIGURES

Other characteristics and advantages of the invention will become apparent from the following detailed description, which is given by way of non-limiting example, with reference to the FIGURE, which shows a schematic cross-sectional view of an external part respectively according to a preferred exemplary embodiment of the present invention.

It should be noted that the FIGURE is not drawn to scale for clarity reasons.

### DETAILED DESCRIPTION OF THE INVENTION

The present invention relates to an external part 10 used in horology, jewellery or fine jewellery, comprising a substrate 100 having a support face 101 made of a material comprising at least 50% by mass of aluminium.

The external part 10 according to the invention is schematically shown in the FIGURE and is particularly suitable for forming a dial for a timepiece, or any other part of the timepiece, preferably an internal part, such as appliques or hands.

In this specification, the substrate material can be pure aluminium, an aluminium alloy, an aluminium nitride, an aluminium carbide, an aluminium oxide, etc.

The substrate 100 is formed by a body which, in an exemplary embodiment of the invention, is made of a material comprising at least 50% by mass of aluminium. The support face 101 is therefore formed by one face of the body.

In other exemplary embodiments of the invention, the substrate 100 can comprise a body on which a plating comprising at least 50% by mass of aluminium is formed. The support face 101 is therefore formed by a face of the plating.

Naturally, the type of material comprising at least 50% by mass of aluminium determines whether the support face 101 is formed by the body or by the plating. For example, if this material is pure aluminium or an aluminium alloy, it can constitute the body of substrate 100. If this material is aluminium nitride, aluminium carbide or aluminium carbonitride, it can constitute a plating deposited by suitable deposition methods, such as physical vapour phase deposition methods or chemical vapour phase deposition methods. Moreover, if this material is an aluminium oxide, it can constitute a plating produced by anodisation, in a manner known per se to a person skilled in the art.

The external part 10 comprises, on its support face 101, a thin-film dielectric coating 110 that is semi-transparent, that is, at least transparent in the visible field. The layers of the thin-film dielectric coating 110 are each deposited by an ALD method. Each layer in the thin-film dielectric coating 110 has a thickness comprised between one nanometre and a few tens of nanometres. This characteristic makes it possible to protect the support face 101 of the external part 10 from chemical and environmental aggressions, such as humidity, and to colour it by a precisely chosen interference effect in a repeatable and robust way. The thickness of the thin-film dielectric coating 110 is therefore homogeneous and consistent across its entire surface.

The support face 101 can be structured by mechanical machining, for example by manual engraving or machining with a numerically controlled machine tool, by chemical machining or by laser machining. The structure is formed by hollows and peaks, the distance between the hollows and peaks being, for example, at least 1 μm, and its appearance is advantageously preserved by the thin-film dielectric coating 110.

The thin-film dielectric coating 110 is formed by at least two thin dielectric layers, including a base layer 111 overlying the support face 101 and a terminal layer 112. The base layer 111 is advantageously made of Al₂O₃, and the terminal layer 112 is advantageously made of TiO₂.

In particular, the terminal layer 112 made of TiO₂ advantageously ensures the chemical protection of the external part.

In the preferred exemplary embodiment of the invention shown in the FIGURE, the thin-film dielectric coating 110 comprises four intermediate layers 113 deposited between the base layer 111 and the terminal layer 112. These intermediate layers 113 are made alternately of TiO₂ and Al₂O₃, such that the intermediate layer 113 overlying the base layer 111 is made of TiO₂ and the layer in contact with the terminal layer 112 is made of Al₂O₃.

In other exemplary embodiments, the thin-film dielectric coating 110 can comprise more or fewer than four intermediate layers 113, provided that there is an even number of them. In other words, the thin-film dielectric coating 110 can comprise at least two layers.

Advantageously, the base layer 111 has excellent chemical affinity with the support face 101 on which it is deposited, which ensures very good adhesion of the base layer 111 and therefore of the thin-film dielectric coating 110, and makes it possible to increase the deposition rate of the base layer 111.

The thin-film dielectric coating 110 imparts an interference colour to the external part 10, the hue of which depends on the thickness of each layer of thin-film dielectric coating 110, on their arrangement and number, and on the material of the support face 101. Thus, the interference colour generated by the characteristics of the invention is advantageously very precise.

In the preferred exemplary embodiment of the invention, the layers in the thin-film dielectric coating 110 have thicknesses chosen so as to impart an interference colour to the external part 10 characterised, in the CIELAB space in the reflection mode of the standardised illuminant D65, with an observer of 10° and a measurement geometry of di:8°, by the parameters L* =[75; 85], a*=[−45; −35], b*=[5; 15], and more specifically by the parameters L*=79, a*=−39, b*=8.

Thus, in this first variant, the external part 10 has a light green or turquoise green appearance.

In this example, each layer in the thin-film dielectric coating 110 has a thickness comprised between one and a few tens of nanometres, for example between 1 nm and 90 nm. In particular, the base layer 111 has a thickness comprised between 1 nm and 10 nm, the intermediate layers 113 have a thickness comprised between 20 nm and 90 nm, and the terminal layer 112 has a thickness comprised between 55 nm and 65 nm. More specifically, the intermediate layers 113, taken successively from the intermediate layer 113 closest to the base layer 111 to the intermediate layer 113 closest to the terminal layer 112, can have the following thicknesses, respectively: between 25 nm and 30 nm, between 75 nm and 85 nm, between 15 nm and 25 nm, and between 15 nm and 25 nm.

More generally, it should be noted that the embodiments and uses considered above have been described by way of non-limiting examples, and that other variants are therefore conceivable.

1. An external part (10) used in horology, jewellery or fine jewellery, characterised in that it comprises a substrate (100) having a support face (101) made of a material comprising at least 50% by mass of aluminium, on which is deposited a semi-transparent thin-film dielectric coating (110) comprising at least two layers, including a base layer (111) made of Al₂O₃ overlying the support face (101), and a terminal layer (112) made of TiO₂.

2. The external part (10) according to claim 1, comprising an even number of intermediate layers (113), and at least two of said intermediate layers (113) being deposited between the base layer (111) and the terminal layer (112) and being alternately made of TiO₂ and Al₂O₃ such that the intermediate layer (113) overlying the base layer (111) is made of TiO₂ and the layer in contact with the terminal layer (112) is made of Al₂O₃.

3. The external part (10) according to claim 1, in which the substrate (100) is formed by a body made of pure aluminium or of aluminium alloy and comprising the support face (101).

4. The external part (10) according to claim 1, in which the substrate (100) comprises a body on which is formed a plating made of aluminium nitride, aluminium carbide, aluminium oxide or aluminium carbonitride, the plating comprising the support face (101).

5. The external part (10) according to claim 2, in which the thin-film dielectric coating (110) comprises four intermediate layers (113).

6. The external part (10) according to claim 5, in which the layers in the thin-film dielectric coating (110) have thicknesses chosen so as to impart an interference colour to the external part (10) characterised, in the CIELAB space in the reflection mode of the standardised illuminant D 65, with an observer of 10°and a measurement geometry of di: 8°, by the parameters L*=[75; 85], a*=[−45; −35], b*=[5; 15].

7. The external part (10) according to claim 6, in which the base layer (111) has a thickness comprised between 1 nm and 10 nm, the intermediate layers (113) have a thickness comprised between 20 nm and 90 nm and the terminal layer (112) has a thickness comprised between 55 nm and 65 nm.

8. The external part (10) according to claim 7, in which the intermediate layers (113) taken successively from the intermediate layer (113) closest to the base layer (111) to the intermediate layer (113) closest to the terminal layer (112) have a thickness comprised between 25 nm and 30 nm, between 75 nm and 85 nm, between 15 nm and 25 nm and between 15 nm and 25 nm, respectively.
